(19) United States
(12) Patent Application Publication
(10) Pub. No.: US 2026/0120977 A1
(43) Pub. Date: Apr. 30, 2026

(54) SYSTEMS AND METHODS FOR USING CAPACITIVE SENSING TO DEBOUNCE A MECHANICAL BUTTON

(71) Applicant: Bose Corporation, Framingham, MA (US)

(72) Inventor: Theodore Bennett, Brookline, NH (US)

(73) Assignee: Bose Corporation, Framingham, MA (US)

(21) Appl. No.: 18/929,855

(22) Filed: Oct. 29, 2024

(51) Int. Cl. H01H 13/14

(52) U.S. Cl. CPC H01H 13/14; H01H 2239/006; H01H 2300/024; H01H 2300/052

(57) ABSTRACT

A device including a mechanical button, a capsense circuit, and a microcontroller is provided. The mechanical button is configured to generate an input signal. The capsense circuit is electrically coupled to the mechanical button. The capsense circuit is configured to (1) measure, while in a scanning state, a capacitance corresponding to the input signal; (2) enter a debouncing state in response to the capacitance exceeding an actuation threshold; (3) generate, while in the debouncing state, a debounced signal in response to the capacitance remaining above the actuation threshold for a predetermined period; and (4) transmit the debounced signal to a microcontroller to initiate a function.

### FIELD OF THE DISCLOSURE

The present disclosure is generally directed to debouncing a mechanical button, and more specifically, to systems and methods for using capacitive sensing to debounce a mechanical button.

### BACKGROUND

Physical buttons and switches are mechanical devices with springs and metal contacts causing some degree of natural bounce. This natural bounce can cause an internal connection of the button to be made and broken several times (referred to as “bounces”) each time the button is pressed by a user. In digital electronics, these extra bounces can be detected and interpreted as intentional inputs, also referred to as false positives. These false positives can lead to issues in the signal processing chain. In some conventional systems, these false positives are filtered out using a “debouncing” process. In these systems, the debouncing is performed by a microcontroller, such as by electrically connecting the physical button to a general-purpose input/output (GPIO) port of the microcontroller. However, using the microcontroller to debounce an electrical signal from the mechanical button requires constant sampling of the GPIO port. The sampled signal is then debounced by a processor of the microcontroller executing software stored in a memory of the processor. This constant sampling and debouncing of the input signal from the mechanical button requires processing cycles of the microcontroller, leading to increased power consumption. This increased power consumption can be a particular issue with battery powered devices.

### SUMMARY

The present disclosure is generally directed to systems and methods for debouncing a mechanical button of a device, such as a wearable audio device. The device includes a mechanical button, a capsense circuit, and a microcontroller configured to implement a function corresponding to the mechanical button. The microcontroller may be powered by a battery embedded within the device. The mechanical button is arranged in the device such that it may be actuated by a user. The capsense circuit is electrically coupled to the mechanical button and the microcontroller. The capsense circuit is configured to operate in at least two states: (1) a scanning state and (2) a debouncing state. While in the scanning state, the capsense circuit is configured to determine if the mechanical button has been pressed. During the scanning state, the capsense circuit measures a capacitance corresponding to the mechanical button according to a sample rate. If the measured capacitance exceeds an actuation threshold indicating that the mechanical button may have been actuated, the capsense circuit enters the debouncing state to determine if the press was an authentic button press or a false positive. In the debouncing state, the capsense circuit continues to measure the capacitance corresponding to the mechanical button according to the sample rate. If the measured capacitance remains above the actuation threshold for a predetermined period, the capsense circuit generates a debounced signal (such as a signal having a binary high voltage) indicative of an authentic button press. If not, the capsense circuit reenters the scanning state, essentially discarding the detected button presses as false positives or bounces. The debounced signal is then provided to the microcontroller for further processing.

In some examples, the microcontroller is in sleep mode prior to receiving the debounced signal, such that the debounced signal awakens the microcontroller upon receipt. In this way, the capsense circuit limits the power consumption of the microcontroller by only awakening the microcontroller if an authentic button press has been received. In some examples, the debounced signal triggers the microcontroller to perform one or more functions. If the microcontroller is installed in a wearable audio device, the debounced signal could adjust characteristics of an audio output signal provided to an acoustic transducer, such as raising or lowering volume. In other examples, the debounced signal could trigger the microcontroller to form a wireless connection (such as a Bluetooth connection) with another device.

In some examples, the actuation threshold may range from 1 picofarad to 20 picofarads. Similarly, the predetermined period during which an authentic button press is confirmed may range from 1 millisecond to 50 milliseconds. Further, the sample rate may range from 20 kilohertz to 150 kilohertz.

Generally, in one aspect, a device is provided. The device includes a mechanical button. The mechanical button is configured to generate an input signal.

The device further includes a capsense circuit. The capsense circuit is electrically coupled to the mechanical button. The capsense circuit is configured to measure, while in a scanning state, a capacitance corresponding to the input signal.

The capsense circuit is further configured to enter a debouncing state in response to the capacitance exceeding an actuation threshold.

The capsense circuit is further configured to generate, while in the debouncing state, a debounced signal in response to the capacitance remaining above the actuation threshold for a predetermined period

The capsense circuit is further configured to transmit the debounced signal to a microcontroller to initiate a function.

According to an example, the microcontroller is in sleep mode prior to receiving the debounced signal from the capsense circuit.

According to an example, the debounced signal is configured to awaken the microcontroller.

According to an example, the actuation threshold ranges from 1 picofarad to 20 picofarads.

According to an example, the predetermined period ranges from 1 millisecond to 50 milliseconds.

According to an example, the capsense circuit measures the capacitance according to a sample rate ranging from 20 kilohertz to 1500 kilohertz.

According to an example, the capsense circuit is further configured to reenter the scanning state if, during the debouncing state, the second capacitance falls below the actuation threshold.

According to an example, the device further includes a battery. The battery is configured to power the microcontroller.

According to an example, the device further includes an acoustic transducer electrically coupled to the microcontroller.

According to an example, the function initiated by the debounced signal adjusts audio generated by the acoustic transducer.

Generally, in another aspect, a method for debouncing a mechanical button of a device is provided. The method includes (1) measuring, via a capsense circuit in a scanning state, a capacitance corresponding to an input signal generated by the mechanical button; (2) configuring the capsense circuit to enter a debouncing state in response to the capacitance exceeding an actuation threshold; (3) generating, while the capsense circuit is in the debouncing state, a debounced signal in response to the capacitance remaining above the actuation threshold for a predetermined period; and (4) transmitting, via the capsense circuit, the debounced signal to a microcontroller to initiate a function.

According to an example, the microcontroller is in sleep mode prior to receiving the debounced signal from the capsense circuit.

According to an example, the debounced signal is configured to awaken the microcontroller.

According to an example, the actuation threshold ranges from 1 picofarad to 20 picofarads.

According to an example, the predetermined period ranges from 1 millisecond to 50 milliseconds.

According to an example, the capsense circuit measures the capacitance according to a sample rate ranging from 20 kilohertz to 1500 kilohertz.

According to an example, the capsense circuit is further configured to reenter the scanning state if, during the debouncing state, the second capacitance falls below the actuation threshold.

According to an example, the device further comprises a battery configured to power the microcontroller.

According to an example, the device further comprises an acoustic transducer electrically coupled to the microcontroller.

According to an example, the function initiated by the debounced signal adjusts audio generated by the acoustic transducer.

In various implementations, a processor or controller can be associated with one or more storage media (generically referred to herein as “memory,” e.g., volatile and non-volatile computer memory such as ROM, RAM, PROM, EPROM, and EEPROM, floppy disks, compact disks, optical disks, magnetic tape, Flash, OTP-ROM, SSD, HDD, etc.). In some implementations, the storage media can be encoded with one or more programs that, when executed on one or more processors and/or controllers, perform at least some of the functions discussed herein. Various storage media can be fixed within a processor or controller or can be transportable, such that the one or more programs stored thereon can be loaded into a processor or controller so as to implement various aspects as discussed herein. The terms “program” or “computer program” are used herein in a generic sense to refer to any type of computer code (e.g., software or microcode) that can be employed to program one or more processors or controllers.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also can appear in any disclosure incorporated by reference should be accorded a meaning most consistent with the particular concepts disclosed herein.

Other features and advantages will be apparent from the description and the claims.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the various embodiments.

FIG. 1 is a front view of a wearable audio device including a mechanical button, in accordance with an example.

FIG. 2 is a functional block diagram of aspects of a system for debouncing a mechanical button, in accordance with an example.

FIG. 3 is a functional block diagram of the capsense circuit of the system of FIG. 2, in accordance with an example.

FIG. 4 is a flow chart of a method for debouncing a mechanical button of a device, in accordance with an example.

### DETAILED DESCRIPTION

The present disclosure is generally directed to systems and methods for debouncing a mechanical button of a device, such as a wearable audio device. The device includes a mechanical button, a capsense circuit, and a microcontroller configured to implement a function corresponding to the mechanical button. The mechanical button is arranged in the device such that it may be actuated by a user. The capsense circuit is electrically coupled to the mechanical button and the microcontroller. The capsense circuit is configured to operate in at least three states: (1) a scanning state and (2) a debouncing state. While in the scanning state, the capsense circuit is configured to determine if the mechanical button has been pressed. During the scanning state, the capsense circuit measures a capacitance corresponding to the mechanical button according to a sample rate. If the measured capacitance exceeds an actuation threshold indicating that the mechanical button may have been actuated, the capsense circuit enters the debouncing state to determine if the press was an authentic button press or a false positive. In the debouncing state, the capsense circuit continues to measure the capacitance corresponding to the mechanical button according to the sample rate. If the measured capacitance remains above the actuation threshold for a predetermined period, the capsense circuit generates a debounced signal indicative of an authentic button press. If not, the capsense circuit reenters the scanning state, essentially discarding the detected button presses as false positives or bounces. The debounced signal is then provided to the microcontroller for further processing.

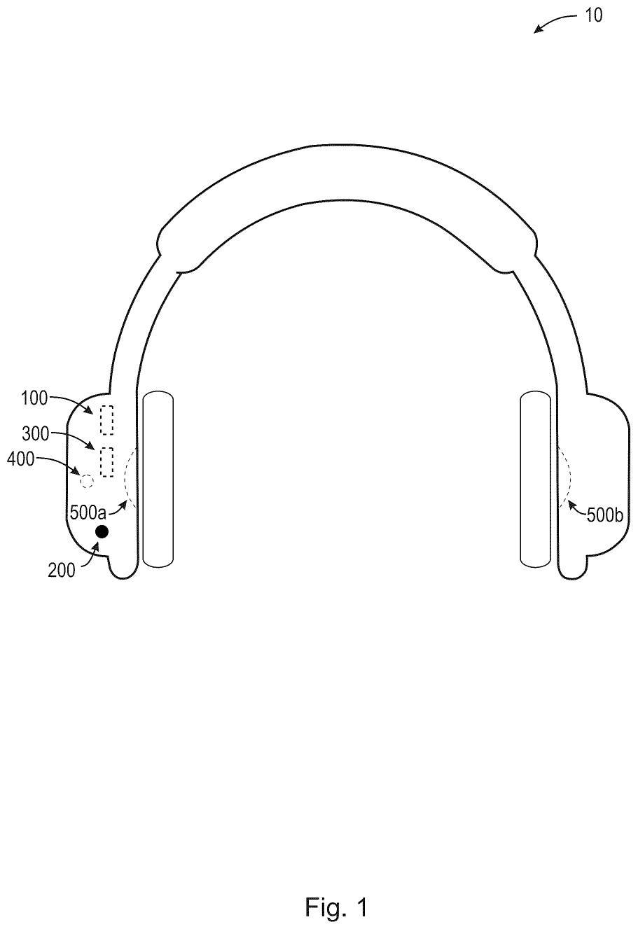

The following description should be read in view of FIGS. 1-4.

The term “wearable audio device,” as used in this application, in addition to including its ordinary meaning or its meaning known to those skilled in the art, is intended to mean a device that fits around, on, in, or near an ear (including open-ear audio devices worn on the head or shoulders of a user) and that radiates acoustic energy into or towards the ear. Wearable audio devices are sometimes referred to as headphones, earphones, earpieces, headsets, earbuds or sport headphones, and can be wired or wireless. A wearable audio device includes an acoustic driver to transduce audio output signals to acoustic energy. The acoustic driver can be housed in an earcup. While some of the figures and descriptions following can show a single wearable audio device, having a pair of earcups (each including an acoustic driver) it should be appreciated that a wearable audio device can be a single stand-alone unit having only one earcup. Each earcup of the wearable audio device can be connected mechanically to another earcup or headphone, for example by a headband and/or by leads that conduct audio signals to an acoustic driver in the ear cup or headphone. A wearable audio device can include components for wirelessly receiving audio signals. A wearable audio device can include components of an active noise reduction (ANR) system. Wearable audio devices can also include other functionality such as a microphone so that they can function as a headset. While the non-limiting example of FIG. 1 depicts the wearable audio device 100 as an audio headset with a pair of ear cups, the wearable audio device 100 described below may be any of the aforementioned types of devices.

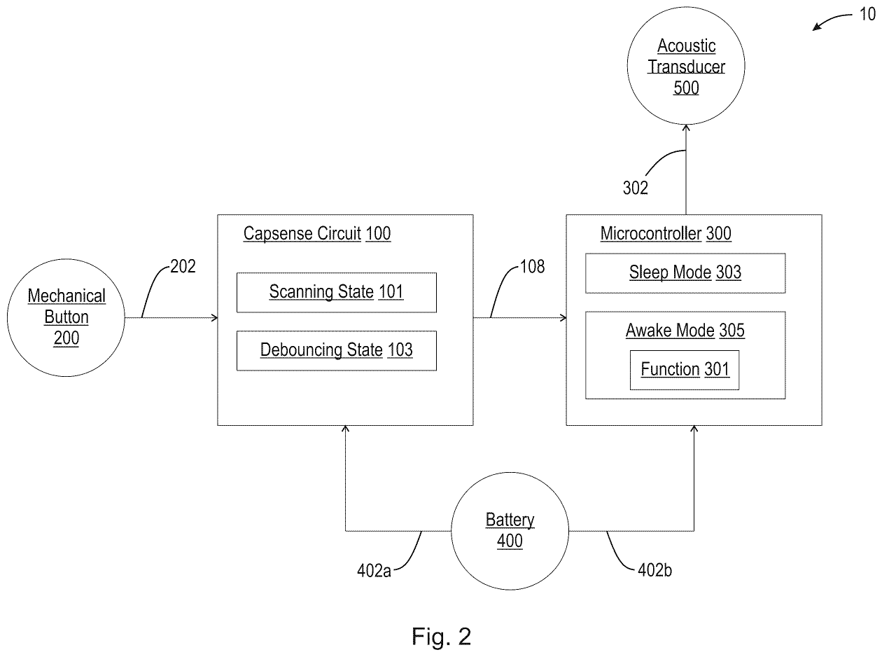

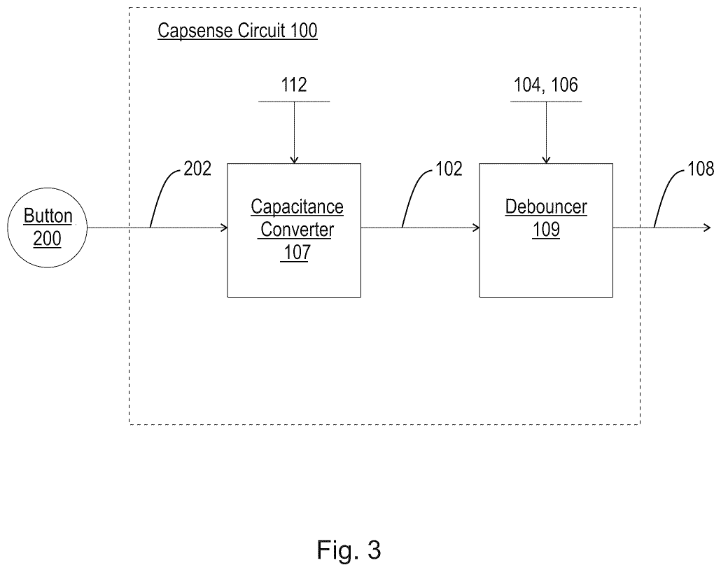

FIG. 1 illustrates a non-limiting example of a device 10. In the example of FIG. 1, the device is embodied as a wearable audio device, in particular an audio headset. However, in other examples, the device 10 may be a device other than a wearable audio device. Broadly, in the example of FIG. 1, the device 10 includes a capsense circuit 100, a mechanical button 200, a microcontroller 300, a battery 400, and a pair of acoustic transducers 500a, 500b. The mechanical button 200 is configured to receive a user input (in the form of a physical button press) and to translate that user input into an electrical signal (shown as input signal 202 in FIGS. 2 and 3) with the goal of triggering the microcontroller 300 to execute a function. In some examples, the mechanical button 200 may be used to raise or lower volume, select audio to be rendered by the acoustic transducer, form a wireless connection (such as a Bluetooth connection) between the device 10 and a second device, etc.

The mechanical button 200 is a physical button comprising internal springs and metal contacts. These springs and metal contacts are configured to form an internal connection when the mechanical button 200 is pressed. However, the internal connection of the button 200 can be made and broken several times (also known as “bounces”) each time the button is pressed, which can lead to the microcontroller 300 detecting several false positives. For example, if the button is configured to increase audio volume, these several false positives could lead to the volume increasing to an undesired level. The capsense circuit 100 is configured to process the electrical signal from the mechanical button 200 and filter any bounces to prevent the microcontroller 300 from detecting false positives. In some examples, aspects of the capsense circuit 100 described herein may be performed by a programmable system-on-chip (PSoC™) 4000S integrated circuit available from Infineon®, though other commercially available PSoC™ integrated circuits may be used instead. The battery 400 may be configured to power the capsense circuit 100 and the microcontroller 300. Accordingly, processing false positives may cause the microcontroller 300 to unnecessarily consume battery power, reducing the battery life for the device 10 as a whole. The acoustic transducers 500a, 500b may be configured to generate audio based on signals provided by the microcontroller 300. In further examples, the capsense circuit 100 may be used to debounced electrical signals generated by a plurality of mechanical buttons 200, rather than only the single mechanical button 200 shown in FIG. 1.

FIG. 2 shows a functional block diagram of the components illustrated in FIG. 1. FIG. 2 illustrates a capsense circuit 100, a mechanical button 200, a microcontroller 300, a battery 400, and an acoustic transducer 500. The mechanical button 200 provides an input signal 202 to the capsense circuit 100. The input signal 202 is indicative of any button presses performed by a user on the mechanical button 200. For example, the input signal 202 may have a high voltage when the mechanical button 200 is pressed (thereby closing the internal connection of the mechanical button 200) and a low voltage when the mechanical button 200 is not pressed. Further, the input signal 202 may alternate between high and low voltage for brief periods due to bounces when the mechanical button 200 is pressed.

The capsense circuit 100 is configured to monitor the input signal 202 and operate in one of two states; (1) a scanning state 101 and (2) a debouncing state 103. Generally, the capsense circuit 100 analyzes the capacitance of the input signal 202 to determine if the mechanical button 200 was actually pressed. If so, the capsense circuit 100 generates a debounced signal 108 without any of the false positives or bounces which may have been present in the input signal 202. For example, the debounced signal 108 may be an electrical signal having a binary high voltage corresponding to the length of the button press.

The debounced signal 108 is then provided to the microcontroller 300. The microcontroller may include a processor and a memory. The microcontroller 300 may include additional components, such as a transmitter, a receiver, and/or a transceiver to wirelessly transmit and/or receive data. The microcontroller 300 is configured to execute a function 301 (increase or decrease audio output volume, pair the device 10 with a second device, etc.) based on the debounced signal 108. The microcontroller 300 may be configured to operate in at least two modes; sleep mode 303 and awake mode 305. In sleep mode 303, most of the aspects (including the function 301) of the microcontroller 300 are deactivated, causing the microcontroller 300 to consume a minimal amount of power from the battery 400. In awake mode, most of the aspects of the microcontroller 300 are active, causing the microcontroller 300 to consume significantly more power than when the microcontroller 300 is in sleep mode 303. The microcontroller 300 may enter sleep mode 303 after a period of inactivity. In the example of FIG. 2, the microcontroller 300 may be in low power sleep mode 303 prior to receiving the debounced signal 108 from the capsense circuit 100. Upon receiving the debounced signal 108, the microcontroller 300 enters the awake mode 305, and certain aspects of the microcontroller 300 are reactivated, increasing power consumption. In the awake mode 305, the microcontroller 300 may execute the function 301 based on the debounced signal 108. In some examples, the microcontroller 300 may then generate an audio output signal 302 based on the debounced signal 108 and/or the function 301. For example, the volume of the audio output signal 302 may be controlled by the debounced signal 108 and/or the function 301. The audio output signal 302 is then provided to the acoustic transducer 500 for playback to the user.

As further shown in FIG. 2, the battery 400 provides a first power signal 402a to power the capsense circuit 100 and a second power signal 402b to power the microcontroller 300. Conventional debouncing uses the processor of the microcontroller 300 to (1) continually sample the input signal 202 and then (2) debounce the input signal 202 using software stored in the memory of the microcontroller 300. This continual sampling and debouncing requires microcontroller processing cycles (and therefore additional power consumption) which can drain the battery 400. In the present example, the capsense circuit 100 monitors the input signal 202 from the mechanical button 200 to (1) determine if the mechanical button 200 has received an authentic button press, and, if so, (2) generate a debounced signal 108. Accordingly, the battery 400 continuously provides the first power signal 402a to the capsense circuit 100 to enable this monitoring. However, this monitoring by the capsense circuit 100 enables the microcontroller 300 to exit sleep mode 303 only when a mechanical button press has been detected and the input signal 202 has been debounced. As the capsense circuit 100 uses significantly less power than the microcontroller 300 in the awake mode 305, the total power consumed by both the capsense circuit 100 and the microcontroller 300 is less than a continually sampling and debouncing microcontroller.

FIG. 3 illustrates functional aspects of the capsense circuit 100 in more detail. Unlike the microcontroller 300, the capsense circuit 100 is hardware-based. As shown in FIG. 3, the capsense circuit 100 executes a capacitance converter 107 and a debouncer comparator 109. While the capsense circuit 100 is in the scanning state 101, the capacitance converter 107 captures samples of the input signal 202 from the mechanical button 200 according to a sample rate 112. The capacitance converter 107 translates the samples of the input signal 202 into a capacitance signal 102. The capacitance signal 102 comprises a series of capacitance measurements generated according to the sample rate 112. The sample rate 112 may range from 20 kHz to 1500 kHz.

The capacitance signal 102 is then provided to the debouncer 109. The debouncer 109 is configured to analyze the capacitance signal 102 to determine if the mechanical button 200 has been pressed. The capacitance signal 102 is compared to an actuation threshold 200. In different examples, the actuation threshold 200 may range from 1 picofarad to 20 picofarads. If the capacitance signal 102 exceeds the actuation threshold 104, the capsense circuit 100 enters debouncing mode 103, as the mechanical button 200 appears to have received an authentic button press. To confirm that the capacitance signal 102 represents an actual button press and not a false positive bounce, the capacitance signal 102 is then monitored over a predetermined period 106, such as 1 millisecond to 50 milliseconds. If the capacitance signal 102 exceeds actuation threshold 104 for the predetermined period 106, an authentic button press has been detected, and the capsense circuit 100 generates the debounced signal 108. If not, the capsense circuit 100 reenters the scanning state 101, and the capacitance comparator 109 waits for the capacitance signal 102 to again exceed the actuation threshold 104. The debounced signal 108 may be an electrical signal having a binary high voltage. The debounced signal 108 generated by the debouncer 109 is then outputted by the capsense circuit 100. As shown in FIG. 2, the debounced signal 108 is received by the microcontroller 300 to awaken the microcontroller 300 from sleep mode 303 and to trigger the microcontroller 300 to execute the function 301.

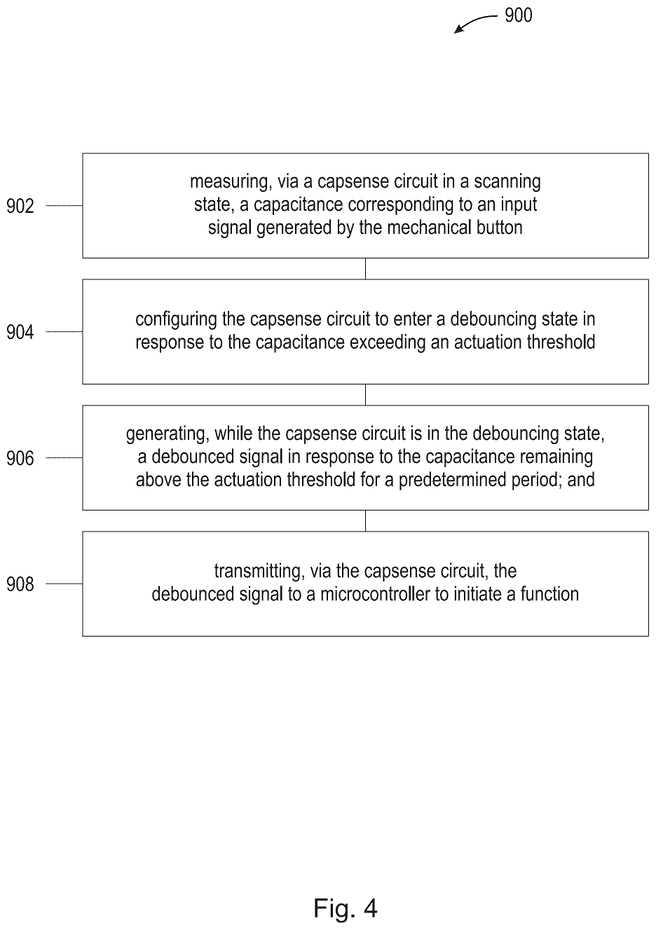

FIG. 4 is a flowchart of a method 900 for debouncing a mechanical button 200 of a device 10. Referring to FIGS. 1-4, the method 900 includes, in step 902, measuring, via a capsense circuit 100 in a scanning state 101, a capacitance 102 corresponding to an input signal 202 generated by the mechanical button 200.

The method 900 further includes, in step 904, configuring the capsense circuit 100 to enter a debouncing state 103 in response to the capacitance 102 exceeding an actuation threshold 104.

The method 900 further includes, in step 906, generating, while the capsense circuit 100 is in the debouncing state 103, a debounced signal 108 in response to the capacitance 102 remaining above the actuation threshold 104 for a predetermined period 106.

The method 900 further includes, in step 908, transmitting, via the capsense circuit 100, the debounced signal 108 to a microcontroller 300 to initiate a function 301.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements can optionally be present other than the elements specifically identified by the “and/or” clause, whether related or unrelated to those elements specifically identified.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements can optionally be present other than the elements specifically identified within the list of elements to which the phrase “at least one” refers, whether related or unrelated to those elements specifically identified.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The above-described examples of the described subject matter can be implemented in any of numerous ways. For example, some aspects can be implemented using hardware, software or a combination thereof. When any aspect is implemented at least in part in software, the software code can be executed on any suitable processor or collection of processors, whether provided in a single device or computer or distributed among multiple devices/computers.

The present disclosure can be implemented as a system, a method, and/or a computer program product at any possible technical detail level of integration. The computer program product can include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some examples, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to examples of the disclosure. It will be understood that each block of the flowchart illustrations and/or block diagrams, and combinations of blocks in the flowchart illustrations and/or block diagrams, can be implemented by computer readable program instructions.

The computer readable program instructions can be provided to a processor of a, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram or blocks.

The computer readable program instructions can also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various examples of the present disclosure. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Other implementations are within the scope of the following claims and other claims to which the applicant can be entitled.

While various examples have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the examples described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific examples described herein. It is, therefore, to be understood that the foregoing examples are presented by way of example only and that, within the scope of the appended claims and equivalents thereto, examples can be practiced otherwise than as specifically described and claimed. Examples of the present disclosure are directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present disclosure.

What is claimed is:

1. A device, comprising:
a mechanical button configured to generate an input signal; and
a capsense circuit electrically coupled to the mechanical button, wherein the capsense circuit is configured to:
measure, while in a scanning state, a capacitance corresponding to the input signal;
enter a debouncing state in response to the capacitance exceeding an actuation threshold;
generate, while in the debouncing state, a debounced signal in response to the capacitance remaining above the actuation threshold for a predetermined period; and
transmit the debounced signal to a microcontroller to initiate a function.

2. The device of claim 1, wherein the microcontroller is in sleep mode prior to receiving the debounced signal from the capsense circuit.

3. The device of claim 2, wherein the debounced signal is configured to awaken the microcontroller.

4. The device of claim 1, wherein the actuation threshold ranges from 1 picofarad to 20 picofarads.

5. The device of claim 1, wherein the predetermined period ranges from 1 millisecond to 50 milliseconds.

6. The device of claim 1, wherein the capsense circuit measures the capacitance according to a sample rate ranging from 20 kilohertz to 1500 kilohertz.

7. The device of claim 1, wherein the capsense circuit is further configured to reenter the scanning state if, during the debouncing state, the capacitance falls below the actuation threshold.

8. The device of claim 1, further comprising a battery configured to power the microcontroller.

9. The device of claim 1, further comprising an acoustic transducer electrically coupled to the microcontroller.

10. The device of claim 9, wherein the function initiated by the debounced signal adjusts audio generated by the acoustic transducer.

11. A method for debouncing a mechanical button of a device, comprising:
measuring, via a capsense circuit in a scanning state, a capacitance corresponding to an input signal generated by the mechanical button;
configuring the capsense circuit to enter a debouncing state in response to the capacitance exceeding an actuation threshold;
generating, while the capsense circuit is in the debouncing state, a debounced signal in response to the capacitance remaining above the actuation threshold for a predetermined period; and
transmitting, via the capsense circuit, the debounced signal to a microcontroller to initiate a function.

12. The method of claim 11, wherein the microcontroller is in sleep mode prior to receiving the debounced signal from the capsense circuit.

13. The method of claim 12, wherein the debounced signal is configured to awaken the microcontroller.

14. The method of claim 11, wherein the actuation threshold ranges from 1 picofarad to 20 picofarads.

15. The method of claim 11, wherein the predetermined period ranges from 1 millisecond to 50 milliseconds.

16. The method of claim 11, wherein the capsense circuit measures the capacitance according to a sample rate ranging from 20 kilohertz to 1500 kilohertz.

17. The method of claim 11, wherein the capsense circuit is further configured to reenter the scanning state if, during the debouncing state, the capacitance falls below the actuation threshold.

18. The method of claim 11, wherein the device further comprises a battery configured to power the microcontroller.

19. The method of claim 11, wherein the device further comprises an acoustic transducer electrically coupled to the microcontroller.

20. The method of claim 19, wherein the function initiated by the debounced signal adjusts audio generated by the acoustic transducer.
